(19) United States
(12) Patent Application Publication
(10) Pub. No.: US 2024/0162012 A1
(43) Pub. Date: May 16, 2024

(54) SUBSTRATE PROCESSING APPARATUS INCLUDING COATING FILM AND INSPECTION METHOD OF COATING FILM FOR SUBSTRATE PROCESSING

(71) Applicant: SEMES CO., LTD., Cheonan-si (KR)

(72) Inventors: Ki Ryong LEE, Cheonan-si (KR); Sun Il KIM, Cheonan-si (KR)

(73) Assignee: SEMES CO., LTD., Cheonan-si (KR)

(21) Appl. No.: 18/388,851

(22) Filed: Nov. 12, 2023

(30) Foreign Application Priority Data
Nov. 11, 2022 (KR) 10-2022-0150707

(51) Int. Cl. H01J 37/32; H01J 37/244

(52) U.S. Cl. CPC H01J 37/32495; H01J 37/244; H01J 2237/24507; H01J 2237/24592

(57) ABSTRACT

Proposed is a method for inspecting for quality of a coating film coated on a component installed in a processing space. The method for inspecting a coating film includes irradiating to irradiate the component with light, observing a coating film to acquire an image of light emitted from the coating film when the irradiating is performed, and inspecting a coating film to inspect the quality of the coating film on the basis of the acquired image of light.

### CROSS REFERENCE TO RELATED APPLICATION

The present application claims priority to Korean Patent Application No. 10-2022-0150707, filed Nov. 11, 2022, the entire contents of which is incorporated by reference herein for all purposes.

### BACKGROUND OF THE INVENTION

### 1. Field of the Invention

The present disclosure relates to a substrate processing apparatus including a coating film and an inspection method of a coating film for a substrate processing apparatus.

### 2. Description of the Related Art

In general, the manufacturing process of semiconductor devices involves steps such as deposition for forming a film on a semiconductor wafer (hereinafter referred to as “substrate”), chemical/mechanical polishing for planarizing the film, photolithography for creating a photoresist pattern on the film, etching for forming the film into a pattern having electrical properties using the photoresist pattern, ion implantation for implanting specific ions into a predetermined region of the substrate, cleaning for removing impurities on the substrate, and inspection for inspecting the surface of the substrate on which a film or pattern is formed.

Some of the processing steps described above may be performed using a plasma chamber such as a plasma etching chamber, a plasma enhanced chemical vapor deposition (PECVD) chamber, a reactive ion etching (RIE) chamber, an electron cyclone resonance (ECR) chamber, and the like. In such processing steps using plasma, wear may occur inside the chamber due to a reaction by the plasma inside each chamber. In order to solve this problem and increase the recyclability of chamber parts, a process of forming a coating film by coating a protective material on the surface of the chamber and the parts applied therein before applying the plasma process is performed. In general, in this coating process, an atmospheric plasma thermal spray coating method in which particles having a size of several tens of lam are laminated, and due to the nature of thermal spray coating, pores or cracks may occur at interfaces between particles during the coating process.

However, conventionally, coating film quality may be analyzed only by conducting cutting and fracture analysis, and thus it is difficult to visually select defective parts when there is a crack inside the part or porosity is higher than before, and analysis and evaluation through the cutting and fracture analysis is time consuming.

To be specific, when selection is made simply based on appearance alone without conducting cutting and fracture analysis, there is a possibility of defective coating parts being applied to a process, which may lead to deterioration in equipment performance. Moreover, there is a problem with delay in verification in case of coating development and condition change when conducting cutting and fracture analysis, and it is impossible to recycle the base material and coating film used for fracture analysis, and unnecessary loss may occur due to analysis time and part consumption.

### SUMMARY OF THE INVENTION

Accordingly, the present disclosure has been made keeping in mind the above problems occurring in the related art, and the present disclosure is intended to provide a technology that can quickly detect a damaged portion of a coating film and evaluate the quality of the coating film without cutting and fracture analysis.

In addition, an objective of the present disclosure is to provide a substrate processing apparatus including a coating film and an inspection method of a coating film for a substrate processing apparatus, capable of inspecting the quality of a coating film while minimizing the effect on a plasma process and the formation of by-products.

Objectives of the present disclosure are not limited thereto, and other objectives not mentioned will be clearly understood by those skilled in the art from the following description and accompanying drawings.

In order to achieve the above objective, according to an embodiment of the present disclosure, there is provided an inspection method of a coating film for a substrate processing apparatus, which is for inspecting for quality of a coating film coated on a component installed in a processing space. The inspection method includes: irradiating to irradiate the component with light; observing a coating film to acquire an image of light emitted from the coating film when the irradiating is performed; and inspecting a coating film to inspect the quality of the coating film on the basis of the acquired image of light.

According to an embodiment of the present disclosure, there may be provided a substrate processing apparatus including: a base material installed in a processing space where substrates are processed; and a coating film formed on the base material. The coating film may include: a first coating layer coated on the base material, having a fluorescence property, and emitting light of a second wavelength when light of a first wavelength is incident thereon; and a second coating layer coated on the first coating layer and transmitting light emitted from the first coating layer.

According to an embodiment of the present disclosure, there may be provided a substrate processing apparatus, including: a chamber configured to provide a processing space in which a substrate is plasma-treated; a coating film formed on a component installed inside the chamber and exposed to plasma; and an inspection unit configured to evaluate quality of the coating film. The coating film may include: a first coating layer coated on a surface of the component, having a fluorescence property, and emitting light of a second wavelength when light of a first wavelength is incident thereon; and a second coating layer coated on the first coating layer and transmitting light emitted from the first coating layer, and the inspection unit may include: a light irradiation part that irradiates the coating film with light of a first wavelength; a vision part that acquires an image of light emitted from the coating film over an entire area of the coating film by the light of the first wavelength; and a determination part that determines a state of the coating film on the basis of the image acquired by the vision part.

A coating film of a substrate processing apparatus according to the present disclosure includes a first coating layer and a second coating layer on the first coating layer. When the coating film is irradiated with light, as the area of the first coating layer corresponding to a damaged portion in the second coating layer emits light, the damaged portion of the second coating layer may be visually observed on the surface of the coating film.

Furthermore, the type of damage present in the second coating layer can be identified on the basis of a damaged form observed as the coating film emits light. Therefore, it is possible to screen the quality of the coating film formed in a processing space without loss due to fracture analysis, and by using a carbon element, negative effects on a process and formation of process by-products can be minimized.

The effects of the present disclosure are not limited to the above effects, and effects not mentioned will be clearly understood by those skilled in the art from this specification and the accompanying drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIGS. 1 and 2 are cross-sectional views of a substrate processing apparatus according to an embodiment of the present disclosure;

FIG. 3 is a cross-sectional view showing a state in which a coating film according to an embodiment of the present disclosure applicable to FIGS. 1 and 2 is coated on a base material;

FIG. 4 is a configuration diagram schematically showing an inspection unit according to an embodiment of the present disclosure that may be applied to the substrate processing apparatus shown in FIGS. 1 and 2 to inspect the coating film of FIG. 3;

FIG. 5 is a view showing a process of confirming a damaged portion of a second coating layer using a light irradiation unit;

FIGS. 6A to 6C are views showing that the amount of light emitted from the coating film changes according to the presence or absence of a third coating layer;

FIG. 7 is a flowchart schematically showing an inspection method of a coating film for a substrate processing apparatus according to an embodiment of the present disclosure; and

FIG. 8 is a flowchart schematically showing an inspection method of a coating film for a substrate processing apparatus according to another embodiment of the present disclosure.

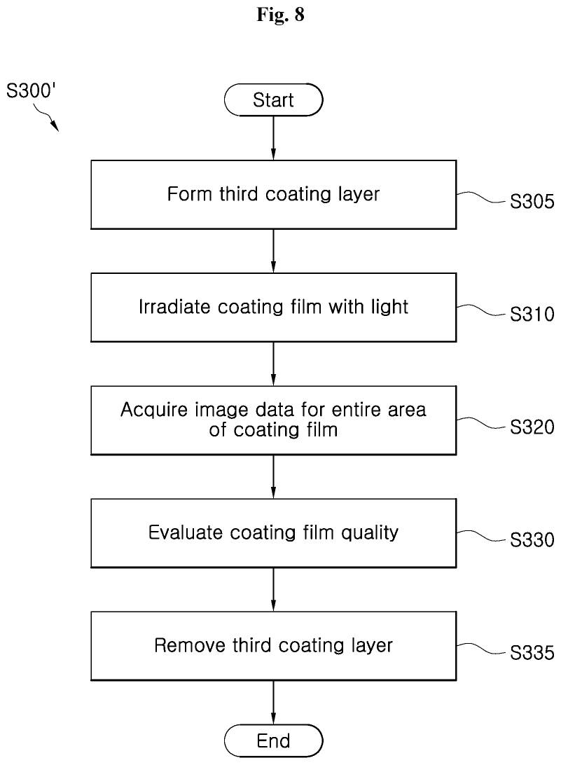

### DETAILED DESCRIPTION OF THE INVENTION

Hereinafter, embodiments of the present disclosure will be described in detail with reference to the accompanying drawings so that those skilled in the art can easily carry out the present disclosure.

However, the present disclosure may be embodied in many different foams and is not limited to the embodiments described herein.

In describing the embodiments of the present disclosure, when it is determined that a detailed description of a related known function or configuration may unnecessarily obscure the subject matter of the present disclosure, the specific description will be omitted, and parts with similar functions and actions will use the same reference numerals throughout the drawings.

Since at least some of the terms used in the specification are defined in consideration of functions in the present disclosure, they may vary according to user, operator intention, custom, and the like. Therefore, the terms should be interpreted based on the contents throughout the specification.

In addition, in this specification, the singular form also includes the plural form unless otherwise specified in the phrase. In the specification, when it is said to include a certain component, this means that it may further include other components without excluding other components unless otherwise stated. When a part is said to be connected (or coupled) with another part, this includes not only the case of being directly connected (or coupled), but also the case of being indirectly connected (or coupled) with another part in between.

Meanwhile, in the drawings, the size or shape of components, and thickness of lines may be somewhat exaggerated for convenience of understanding.

When an element or layer is referred to as “on” another element or layer, it includes both the case where another element or layer is intervened as well as directly on another element or layer. On the other hand, when an element is referred to as “directly on”, it indicates that another element or layer is not intervened.

The spatially relative tams “below”, “beneath”, “lower”, “above”, “upper”, etc. may be used to easily describe the correlation between one element or component and another element or component as shown in the drawings. The spatially relative terms should be understood as encompassing different orientations of elements in use or operation in addition to the orientations shown in the drawings. For example, when elements shown in the drawings are reversed, elements described as “below” or “beneath” other elements may be placed “above” the other elements. Thus, the exemplary term “below” may include orientations of both below and above. Elements may also be oriented in other orientations, and thus spatially relative terms may be interpreted according to orientation.

Although first, second, etc. are used to describe various elements, components and/or sections, it is needless to say that these elements, components and/or sections are not limited by these terms. These terms are only used to distinguish one element, component or section from another element, component or section. Thus, it is needless to say that first element, first component, or first section referred to below may be a second element, second component, or second section within the technical spirit of the present disclosure.

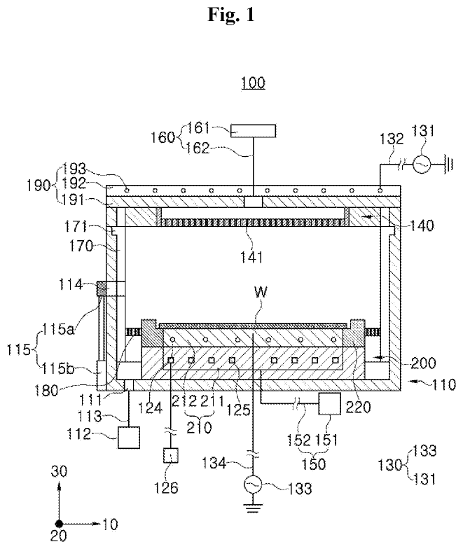

FIG. 1 is a cross-sectional view schematically showing the structure of a substrate processing apparatus according to an embodiment of the present disclosure.

Referring to FIG. 1, a substrate processing apparatus 100 may include a chamber 110, a substrate support unit 200, a plasma generation unit 130, a shower head unit 140, a first gas supply unit 150, a second gas supply unit 160, a wall liner unit 170, a baffle unit 180, and an upper module 190.

The substrate processing apparatus 100 is a system that processes a substrate W (e.g., a wafer) by using an etching process (e.g., a dry etching process) in a vacuum environment. The substrate processing apparatus 100 may process the substrate W using, for example, a plasma process.

The chamber 110 provides a processing space in which a plasma process is performed. The chamber 110 may have an exhaust hole 111 at a lower portion thereof.

The exhaust hole 111 may be connected to an exhaust line 113 in which a pump 112 is mounted. The exhaust hole 111 may discharge reaction by-products produced during the plasma process and gas remaining inside the chamber 110 to the outside of the chamber 110 through the exhaust line 113. In this case, the inner space of the chamber 110 may be decompressed to a predetermined pressure.

The chamber 110 may have an opening 114 formed on the sidewall thereof. The opening 114 may function as a passage through which the substrate W enters and exits the chamber 110. The opening 114 may be configured to be opened and closed by a door assembly 115.

The door assembly 115 may include an outer door 115a and a door actuator 115b. The outer door 115a is provided on the outer wall of the chamber 110. The outer door 115a may be moved in a vertical direction (i.e., in a third direction 30) by means of the door actuator 115b. The door actuator 115b may operate using a motor, hydraulic cylinder, pneumatic cylinder, or the like.

The substrate support unit 200 is installed in the lower inner region of the chamber 110. The substrate support unit 200 may support the substrate W using electrostatic force. However, the present embodiment is not limited thereto. The substrate support unit 200 may support the substrate W in various ways such as mechanical clamping, vacuum, and the like.

When the substrate support unit 200 supports the substrate W using electrostatic force, the substrate support unit 200 may include an electrostatic chuck (ESC) 210 including a base component 211 and a chucking component 212.

The base component 211 supports the chucking component. The base component 211 may be made of, for example, an aluminum component and provided as an aluminum base plate.

The chucking component 212 supports the substrate W placed thereon using electrostatic force. The chucking component 212 may be made of ceramic components and provided as a ceramic plate or a ceramic puck, and may be combined with the base component 211 to be fixed on the base component 211.

A bonding layer 213 may be formed between the base component 211 and the chucking component 212 formed thereon.

A focus ring 220 may be disposed on an edge area of the substrate support unit 200. The focus ring 220 has a ring shape and may be disposed along the circumference of the electrostatic chuck 210. An upper surface of the focus ring 220 may have an outer portion higher than an inner portion. For example, the inner portion of the upper surface of the focus ring 220 may be positioned at the same level as the upper surface of the chucking component 212. The inner portion of the upper surface of the focus ring 220 may support an edge area of the substrate W supported by the chucking component 212. The focus ring 220 may control the electric field so that the plasma density is uniformly distributed over the entire area of the substrate W. As a result, plasma is uniformly formed over the entire area of the substrate W so that each area of the substrate W may be uniformly etched.

The first gas supply unit 150 may supply heat transfer gas to the lower surface of the substrate W. The heat transfer gas serves as a medium to help heat exchange between the substrate W and the electrostatic chuck 210. The entire temperature of the substrate W may be made uniform by the heat transfer gas. The heat transfer gas contains an inert gas. For example, the heat transfer gas may include helium (He) gas. The first gas supply unit 150 may include a first gas supply source 151 and a first gas supply line 152.

The first gas supply source 151 may supply He gas as a first gas. The first gas from the first gas supply source 151 may be supplied to the lower surface of the substrate W through the first gas supply line 152.

A heating member 124 and a cooling member 125 are provided to maintain a process temperature of the substrate W when an etching process is in progress inside the chamber 110. For this purpose, the heating member 124 may be provided as a heating wire, and the cooling member 125 may be provided as a cooling line through which refrigerant flows.

The heating member 124 and the cooling member 125 may be installed inside the electrostatic chuck 210 so that the substrate W may maintain the process temperature. As an example, the heating member 124 may be installed inside the chucking component 122, and the cooling member 125 may be installed inside the base component 121.

Meanwhile, the cooling member 125 may receive a refrigerant using a chiller 126. The chiller 126 may be installed outside the chamber 110.

The plasma generation unit 130 generates plasma from gas remaining in a discharge space. At this time, the discharge space means a space above the electrostatic chuck 210 in the inner space of the chamber 110.

The plasma generation unit 130 may generate plasma in the discharge space inside the chamber 110 using an inductively coupled plasma (ICP) source. In this case, the plasma generation unit 130 may use an antenna unit 193 installed on an upper module 190 as an upper electrode and use the electrostatic chuck 210 as a lower electrode.

However, the present embodiment is not limited thereto. The plasma generation unit 130 may generate plasma in the discharge space inside the chamber 110 using a capacitively coupled plasma (CCP) source. In this case, as shown in FIG. 2, the plasma generation unit 130 may use the shower head unit 140 as an upper electrode and the electrostatic chuck 210 as a lower electrode. FIG. 2 is a cross-sectional view schematically showing the structure of a substrate processing apparatus according to another embodiment of the present disclosure.

The plasma generation unit 130 may include an upper electrode, a lower electrode, an upper power source 131 and a lower power source 133.

The upper power source 131 applies power to the upper electrode, that is, the antenna unit 193. Such an upper power source 131 may be provided to control the characteristics of plasma. The upper power source 131 may be provided to adjust ion bombardment energy, for example.

Although a single upper power source 131 is shown in FIG. 1, it is also possible to have a plurality of upper power sources 131 in this embodiment. When the plurality of upper power sources 131 is provided, the substrate processing apparatus 100 may further include a first matching network (not shown) electrically connected to the plurality of upper power sources.

The first matching network may match frequency powers of different magnitudes input from each upper power source and apply the matched frequency powers to the antenna unit 193.

Meanwhile, a first impedance matching circuit (not shown) may be provided on a first transmission line 132 connecting the upper power source 131 and the antenna unit 193 for the purpose of impedance matching.

The first impedance matching circuit may act as a lossless passive circuit to effectively (i.e., maximally) transfer electrical energy from the upper power source 131 to the antenna unit 193.

The lower power source 133 applies power to the lower electrode, that is, the electrostatic chuck 210. The lower power source 133 may serve as a plasma source for generating plasma or may serve to control characteristics of plasma together with the upper power source 131.

Although a single lower power source 133 is shown in FIG. 1, it is also possible to have a plurality of lower power sources 133 in this embodiment like the upper power source 131. When the plurality of lower power sources 133 is provided, the substrate processing apparatus 100 may further include a second matching network (not shown) electrically connected to the plurality of lower power sources.

The second matching network may match frequency powers of different magnitudes input from each lower power source and apply the matched frequency powers to the electrostatic chuck 210.

Meanwhile, a second impedance matching circuit (not shown) may be provided on a second transmission line 134 connecting the lower power source 133 and the electrostatic chuck 210 for the purpose of impedance matching.

Like the first impedance matching circuit, the second impedance matching circuit may act as a lossless passive circuit to effectively (i.e., maximally) transfer electrical energy from the lower power source 133 to the electrostatic chuck 210.

The shower head unit 140 may be vertically opposed to the electrostatic chuck 210 inside the chamber 110. The shower head unit 140 may include a plurality of gas feeding holes 141 to inject gas into the chamber 110, and may be provided to have a larger diameter than the electrostatic chuck 210.

Meanwhile, the shower head unit 140 may be made of a silicon component, or may be made of a metal component.

The second gas supply unit 160 supplies process gas (second gas) into the chamber 110 through the shower head unit 140. The second gas supply unit 160 may include a second gas supply source 161 and a second gas supply line 162.

The second gas supply source 161 supplies an etching gas used to process the substrate W as a process gas. The second gas supply source 161 may supply a gas containing a fluorine component (e.g., a gas such as SF6 or CF4) as an etching gas.

A single second gas supply source 161 may be provided to supply etching gas to the shower head unit 140. However, the present embodiment is not limited thereto. A plurality of second gas supply sources 161 may be provided to supply process gas to the shower head unit 140.

The second gas supply line 162 connects the second gas supply source 161 and the shower head unit 140. The second gas supply line 162 transfers the process gas supplied from the second gas supply source 161 to the shower head unit 140 so that the etching gas may flow into the chamber 110.

Meanwhile, when the shower head unit 140 is divided into a center zone, a middle zone, and an edge zone, the second gas supply unit 160 may further include a gas distributor (not shown) and a gas distribution line (not shown) to supply process gas to each area of the shower head unit 140.

The gas distributor distributes the process gas supplied from the second gas supply source 161 to each area of the shower head unit 140. The gas distributor may be connected to the second gas supply source 161 through the second gas supply line 162.

The gas distribution line connects the gas distributor and each area of the shower head unit 140. Through the gas distribution line, the process gas distributed by the gas distributor may be transferred to each area of the shower head unit 140.

Meanwhile, the second gas supply unit 160 may further include a third gas supply source (not shown) for supplying deposition gas.

The third gas supply source supplies gas to the shower head unit 140 to protect the side surface of the substrate W pattern and enable anisotropic etching. The third gas supply source may supply a gas such as C4F8 or C2F4 as a deposition gas.

The wall liner unit 170 protects the inner surface of the chamber 110 from arc discharge generated during process gas excitation and impurities produced during a substrate processing process. The wall liner unit 170 may be provided inside the chamber 110 in a cylindrical shape with upper and lower portions thereof open. Optionally, the wall liner unit 170 may not be provided.

The wall liner unit 170 may be provided adjacent to the inner wall of the chamber 110. The wall liner unit 170 may have a support ring 171 thereon. The support ring 171 protrudes from the upper part of the wall liner unit 170 in an outward direction (i.e., in a first direction 10), and is placed on the upper side of the chamber 110 to support the wall liner unit 170.

The baffle unit 180 serves to exhaust plasma process by-products, unreacted gases, and the like. The baffle unit 180 may be installed between the inner wall of the chamber 110 and the electrostatic chuck 210. The baffle unit 180 may be provided in an annular ring shape and may include a plurality of through holes penetrating in a vertical direction (i.e., in a third direction 30). The baffle unit 180 may control the flow of process gas depending on the number and shape of through holes.

The upper module 190 is installed to cover the open top of the chamber 110. The upper module 190 may include a window member 191, an antenna member 192 and an antenna unit 193.

The window member 191 is formed to cover the top of the chamber 110 to seal the inner space of the chamber 110. The window member 191 may be provided in a plate (e.g., disc) shape, and may be made of an insulating material (e.g., alumina (Al2O3)).

The window member 191 may be formed by including a dielectric window. The window member 191 may have a through hole through which the second gas supply line 162 is inserted. A coating film may be formed on the surface of the window member 191 to suppress generation of particles when a plasma process is performed inside the chamber 110.

The antenna member 192 is installed on top of the window member 191, and may be provided with a space of a predetermined size so that the antenna unit 193 may be disposed therein.

The antenna member 192 may be famed in a cylindrical shape with an open bottom, and may be provided to have a diameter corresponding to that of the chamber 110. The antenna member 192 may be provided to be detachable from the window member 191.

The antenna unit 193 functions as an upper electrode and is equipped with a coil provided to form a closed loop. The antenna unit 193 generates a magnetic field and an electric field inside the chamber 110 based on power supplied from the upper power source 131 to excite gas introduced into the chamber 110 through the shower head unit 140 into plasma.

The antenna unit 193 may be equipped with a planar spiral coil. However, the present embodiment is not limited thereto. The structure or size of the coil may be variously changed by those skilled in the art.

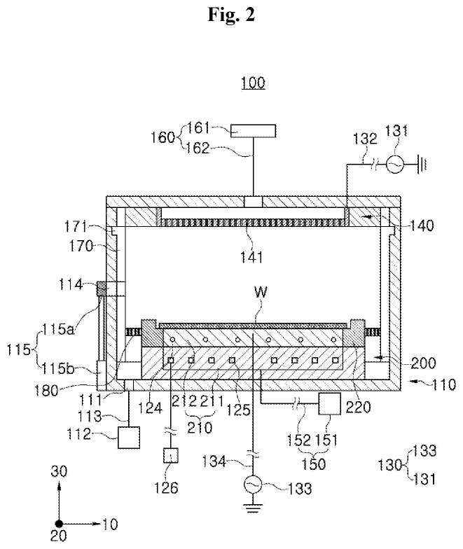

Hereinafter, a coating film 300 and an inspection unit 400 included in the above-described substrate processing apparatus will be described with reference to FIGS. 3 to 6.

FIG. 3 shows a coating film according to an embodiment of the present disclosure. The coating film according to the embodiment of the present disclosure may be formed on components applied to a plasma processing device. To be specific, the coating film according to the embodiment of the present disclosure may be formed, in a narrow view, on the inner wall of the chamber of the plasma processing device and in a broad view, may be formed on the surfaces of various components installed in a plasma processing space.

Referring to FIG. 3, a coating film 300 according to an embodiment of the present disclosure includes a first coating layer 310 and a second coating layer 320.

The first coating layer 310 has a fluorescence property, and may emit light of a second wavelength when light of a first wavelength is incident thereon. At this time, the first wavelength and the second wavelength may be any one selected from infrared rays, visible rays, and ultraviolet rays. For example, light of the first wavelength may be ultraviolet light and light of the second wavelength may be visible light. The first coating layer 310 may be a phosphor including a matrix doped with a dopant. The first coating layer 310 may be included in the range of 0.1 to 50% of the total thickness of the coating film 300.

The dopant may include one or more carbon (C) elements.

The matrix may include, for example, one or more materials selected from yttrium oxide (Y2O3), gadolinium oxide (Gd2O3), yttrium borate (YBO3), aluminum oxide (Al2O3), zinc oxide (ZnO), cerium oxide (CeO2), and lanthanum oxide (La2O3). The matrix may maintain a state in which the second coating layer 320 to be described later and a base material 50 on which the coating film 300 according to the embodiment of the present disclosure is formed are stably bonded to each other. In addition, the matrix, as a phosphor host material, may emit light due to light irradiation when a dopant is added. For example, the matrix of the first coating layer 310 may be yttrium oxide (Y2O3).

In general, the rare earth elements such as europium (Eu), terbium (Tb), and dysprosium (Dy) are added as dopants to phosphor host materials for luminous efficiency. However, when these elements are present inside the coating film, they may have a significant effect the plasma process. By contrast, the carbon element has a relatively low luminous efficiency compared to the elements described above, but its effect on the plasma process and by-product production are also relatively small. Thus, when the first coating layer 310 is formed by adding carbon as a dopant to yttrium oxide (Y2O3), it is possible to have fluorescence properties by light irradiation and at the same time minimize effects on process and formation of by-products. That is, using carbon as a dopant is advantageous in terms of process stability.

When using a thermal spray coating method to form the first coating layer 310 on the base material 50, a process of heating and melting a mixed powder obtained by mixing yttrium oxide powder and carbon powder at an appropriate mixing ratio and spraying the melted mixed powder onto the base material 50 may be performed. The molten powder sprayed onto the base material 50 may be rapidly cooled and solidified to form the first coating layer 310 on the base material 50. In the process of melting and solidifying the mixed powder of yttrium powder and carbon powder, carbon ions are doped into yttrium oxide, and in order to minimize the process effects of carbon ions and the production of by-products, the carbon content used in preparing the mixed powder may fall within the range of 0.01 to 10% by weight based on 100% by weight of yttrium oxide. In addition, the size of carbon particles doped into the matrix is preferably in the range of 10 nm to 30 μm.

At this time, the carbon powder used for manufacturing the mixed powder may be one of graphite, carbon nanotube, and carbon nanofiber, all of which contain carbon elements.

The second coating layer 320 may be coated on the first coating layer 310. That is, the second coating layer 320 may be coated on the surface (upper surface) of the first coating layer 310. The second coating layer 320 is a layer directly exposed to plasma when a plasma process is performed. The second coating layer 320 may transmit light emitted from the first coating layer 310.

The second coating layer 320 may be a material having etching resistance and plasma resistance. Accordingly, the second coating layer 320 may prevent chamber components from being damaged or deformed by plasma, and may maintain plasma stably. The second coating layer 320 may be, for example, yttrium oxide (Y2O3).

Yttrium oxide is a compound containing yttrium, and the yttrium has physical properties of a melting point of 1,495° C., a boiling point of 2,927° C., and a specific gravity of 4.45. The yttrium oxide has excellent plasma resistance. Therefore, even if the base material 50 is exposed to plasma for a long period of time, it is not easily corroded due to the second coating layer 320, and thus, the reusability of expensive chamber components may be increased.

In order to minimize the process effects of the first coating layer 310 including carbon and the generation of process by-products, the thickness of the first coating layer 310 may fall within the range of 0.1% to 50% of the total thickness of the coating film 300. As an example, when the thickness of the entire coating film 300 is 100 μm, the thickness of the first coating layer 310 may have a value ranging from 0.1 to 50 μm, and the second coating layer 320 may have a thickness of (100−thickness of the first coating layer 310) μm.

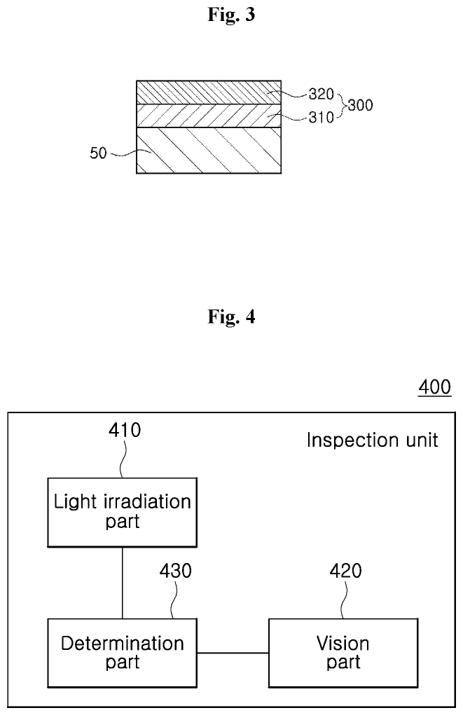

FIG. 4 shows the inspection unit 400 according to an embodiment of the present disclosure. The inspection unit 400 according to an embodiment of the present disclosure may include a light irradiation part 410, a vision part 420, and a determination part 430.

The light irradiation part 410 may irradiate the coating film 300 with light of a first wavelength from inside or outside the processing space. The light of the first wavelength may be ultraviolet light. One or a plurality of light irradiation parts 410 may be provided. When the light irradiation part 410 is provided as one, the light irradiation part 410 may be movably provided to irradiate the entire area of the coating film 300 with the light of the first wavelength. When a plurality of light irradiation parts 410 is provided, the light irradiation parts 410 may be installed at various positions inside or outside the processing space to irradiate the entire area of the coating film 300 with the light of the first wavelength.

When the light irradiation part 410 irradiates the coating film 300 with the light of a first wavelength, light of a second wavelength may be emitted from the first coating layer 310 due to the light of the first wavelength passing through the second coating layer 320 and incident on the first coating layer 310. The light of the second wavelength emitted from the first coating layer 310 may pass through the second coating layer 320 and be observed on the top of the coating film 300. That is, when the coating film 300 is irradiated with light by the light irradiation part 410, the coating film 300 may emit light due to the first coating layer 310. When the second coating layer 320, which is a layer in direct contact with plasma, is uniformly coated on the first coating layer 310 without cracks or pores, the brightness of light observed on the top of the coating film 300 will be uniform. On the other hand, when damage, such as cracks and pores, exists in the second coating layer 320, the brightness of the light observed on the top of the coating film 300 will not be uniform since the thickness of the second coating layer 320 present in the damaged area is different from the thickness of the second coating layer 320 present in the undamaged area. That is, there will be a difference between the intensity of light observed in the area where the second coating layer 320 is damaged and the intensity of light observed in the area where the second coating layer 320 is not damaged.

The vision part 420 may observe the light emitted from the coating film 300 by the light radiated from the light irradiation part 410. The vision part 420 may acquire an image (image data) of light emitted from the entire area of the coating film 300 when the light irradiation part 410 irradiates the coating film 300 with light by imaging the light emitted from the coating film 300 as the first coating layer 310 is emitted by the light radiated from the light irradiation part 410. As an example, the vision part 420 may be provided as an optical camera, but is not limited thereto. One or more optical cameras may be provided and may be installed in various positions or provided to be movable in order to photograph the entire area of the coating film 300. Alternatively, the vision part 420 may be provided as a movable magnifying glass to simply help a user observe the coating film 300. The vision part 420 may transmit the acquired image to the determination part 430 described below.

The determination part 430 may determine the state of the coating film 300 on the basis of the image acquired by the vision part 420. The determination part 430 receives an image when the coating film 300 is irradiated with light by the light irradiation part 410 to from the vision part 420, and may determine that the coating film 300 is defective when the intensity of light observed on the upper surface of the coating film 300 is not uniform.

As such, since the substrate processing apparatus according to the present disclosure includes the inspection unit 400 consisting of the light irradiation part 410, the vision part 420, and the determination part 430, the state of the coating film 300 may be immediately checked in the substrate processing apparatus 100 itself without the need to inspect the state of the coating film 300 using a separate fracture analysis device. In addition, even if the chamber 110 constituting the processing space is not opened, the state of the components included in the substrate processing apparatus 100 may be quickly inspected, and thus the time for inspecting the state of the components may be significantly reduced.

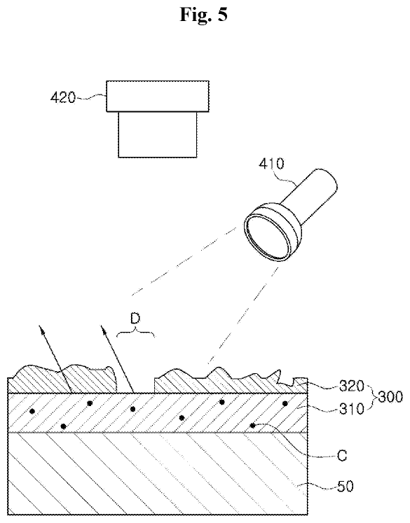

Referring to FIG. 5, as described above, in the coating film 300 according to an embodiment of the present disclosure, the first coating layer 310 is located under the second coating layer 320. Accordingly, when a portion of the second coating layer 320 is damaged, when the damaged portion D of the second coating layer 320 is irradiated with ultraviolet light having a first wavelength by the light irradiation part 410, it may be observed by the vision part 420 that a portion of the first coating layer 310 corresponding to the damaged portion D of the second coating layer 320 emits light. As an example, as the second coating layer 320 is damaged, the second coating layer 320 does not exist on the upper surface of the first coating layer 310 corresponding to the damaged portion D of the second coating layer 320, and thus when the coating film 300 is observed from above, the damaged portion D of the second coating layer 320 of the coating film 300 emits light relatively stronger than the surrounding area, and the damaged portion of the second coating layer 320 may be quickly checked. In addition, since the damaged shape of the second coating layer 320 may be confirmed using the same principle, the type of damage (e.g., crack, pore, etc.) present in the coating film 300 may also be identified. This may be identified not only through the vision part 420 but also by the user's naked eyes. In particular, even the damaged form of the second coating layer 320 may be determined. On the basis of the damaged form of the second coating layer 320, the type of damage present in the second coating layer 320 may also be distinguished.

The base material 50 may be a component or a body included in the processing space of the substrate processing apparatus 100. For example, the base material 50 may be various components constituting the substrate processing apparatus 100, such as the inner wall of the chamber 110, the upper and outer surfaces of the substrate support unit 200, the lower surface of the shower head unit 140, a focus ring 220, a nozzle, and pipes. To be specific, the base material 50 may be surfaces of various components of the substrate processing apparatus 100 that are exposed to plasma during a plasma process. The base material 50 may be a metal or non-metal material. For example, the base material 50 may be aluminum or stainless steel, or a ceramic material (Al2O3, SiO2, AlN), but is not limited thereto. The coating film 300 may be formed on the base material 50. At this time, the coating film 300 may be a light emitting coating film. A method of forming the coating film 300 on the base material 50 may be a thermal spray coating. As an example, methods such as spray coating, physical vapor deposition (PVD) or chemical vapor deposition (CVD) may be used.

For example, the coating film 300 may be formed by melting the above-described materials constituting the coating film 300 using high-temperature heat generated by plasma discharge and spraying the molten materials onto the base material 50. The thickness of the coating film 300 may be variously changed according to the design of the substrate processing apparatus.

The coating film 300 included in the substrate processing apparatus according to the present disclosure is composed of the first coating layer 310 and the second coating layer 320. When the user operates the light irradiation part 410 (see FIG. 4) toward the base material 50, the first coating layer 310 corresponding to the damaged portion D (see FIG. 2) of the second coating layer 320 may emit light. That is, the user may quickly check the damaged portion of the second coating layer 320 with the naked eye without using expensive fracture analysis equipment.

Meanwhile, as described above, since the carbon element has lower luminous efficiency than the rare earth elements conventionally used as dopants, in order to more easily inspect the quality of the coating film 300, a third coating layer 330 having the same physical properties as the first coating layer 310 is famed on the coating film 300 immediately before performing the quality inspection of the coating film 300, and when the quality inspection of the coating film 300 using the light irradiation part 410 is completed, the third coating layer 330 on the second coating layer 320 may be removed. As an example, the third coating layer 330 may be removed using a polishing method, but is not limited thereto.

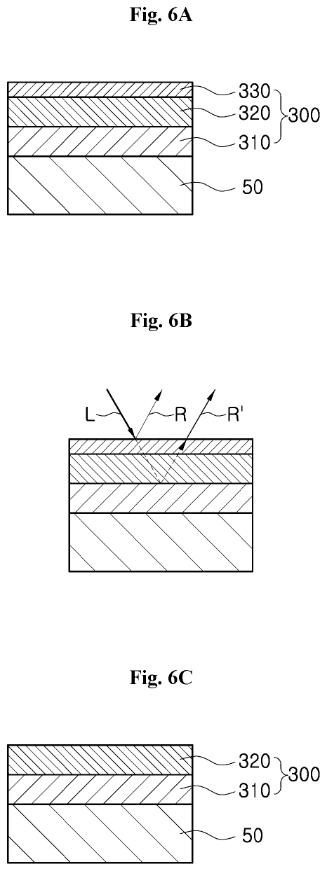

Referring to FIGS. 6A to 6C, when the coating film 300 on which the third coating layer 330 is formed prior to the inspection step receives light of the first wavelength, the amount of light emitted from the coating film 300 may increase. To be specific, as shown in FIG. 6B, when the second coating layer 320 is not damaged at all, light L radiated from the outside may be incident on the first coating layer 310 and the third coating layer 330 and then emitted. Some R of the light of the light L incident to the coating film 300 is emitted by the third coating layer 330, and the remaining light passes through the second coating layer 320 and may be emitted by the first coating layer 310 as light R′ having a reduced intensity. In this case, as the thickness of the second coating layer 320 becomes thinner, the brightness of the light R′ emitted by the first coating layer 310 may increase.

However, in the case of the light observed by the user or the vision part 420, since the combined light R+R′ of the light R emitted by the third coating layer 330 and the light R′ emitted by the first coating layer 310 is observed, the third coating layer 330, When there is no light, a greater amount of light than that observed when the third coating layer 330 does not exist may be observed. That is, by forming the third coating layer 330 on the second coating layer 320, higher luminous efficiency may be realized.

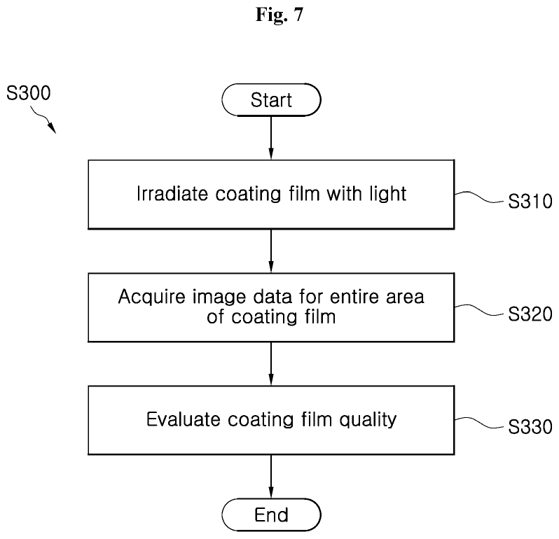

FIG. 7 is a flowchart schematically showing an inspection method (S300) of a coating film for a substrate processing apparatus according to an embodiment of the present disclosure. The inspection method (S300) of a coating film for a substrate processing apparatus according to the embodiment of the present disclosure is a method for inspecting the quality of the coating film 300 coated on the components installed in the substrate processing apparatus 100 including the components coated with the above-described coating layer, and includes: a light irradiation step (S310) of irradiating a component with light; a coating film observation step (S320) of acquiring an image of the coating film in a state of being irradiated; and a coating film inspection step (S330) of inspecting the quality of the coating film on the basis of the acquired image. For convenience of description, redundant descriptions will be omitted.

In the step of light irradiation (S310), a component on which the coating film 300 is formed may be irradiated with light of the first wavelength. In the step (S310) of light irradiation, a component exposed in a processing space in which a substrate is processed may be irradiated with light of the first wavelength. As an example, a user may irradiate the component with ultraviolet rays using a separate ultraviolet irradiation device, and the coating film 300 coated on the component may be irradiated with light of the first wavelength by the above-described light irradiation part 410.

The step of coating film observation (S320) may be a step of observing an image of light emitted from the coating film 300 by the light of the first wavelength radiated toward the component on which the coating film 300 is formed. As previously described, the coating film 300 emits light stemming from the light radiated from the outside due to the first coating layer 310 having a fluorescence property, and depending on whether the second coating layer 320 is damaged, there may be a difference in the uniformity of light emitted from the coating film 300.

The step of coating film observation (S320) may be performed by the vision part 420 described above. As an example, the vision part 420 may be provided as an optical camera, etc. to capture light emitted from the coating film 300 formed on the component when the light irradiation part 410 irradiates the component with light of the first wavelength, and to acquire an image of the light emitted from the entire area of the component. Meanwhile, the step of coating film observation (S320) may be performed by the user's naked eye.

Assuming there is no damage to the coating film 300, when the component is irradiated with light of the first wavelength, in all areas of the coating film 300 famed on the component, the light of the second wavelength emitted from the first coating layer 310 will pass through the second coating layer 320 and be observed on the top of the coating film 300. That is, light of uniform intensity may be observed in all areas of the coating film 300 formed on the component.

On the other hand, assuming there is damage (e.g., cracks, pores) in the coating film 300, to be specific, when the outermost portion of the second coating layer 320 is damaged, a difference occurs between the intensity of light observed on the top of the area where the second coating layer 320 is damaged and the intensity of light observed on the top of the area where the second coating layer 320 is not damaged, and it will not be possible to observe light of uniform intensity in all areas of the coating film 300 formed on the component. Accordingly, the shape of the damaged portion formed on the second coating layer 320 may also be observed by the vision part 420.

The image acquired by the vision part 420 may be used in the coating film inspection step (S330). Alternatively, the quality of the coating film may be directly evaluated on the basis of the user's observations with the naked eye.

In the coating film inspection step (S330), the presence or absence of damage on the coating film 300 may be determined by the image acquired in the coating film observation step (S320), and furthermore, the damaged form may be identified. In addition, based on the damaged form, the type of damage may be identified.

In the coating film inspection step (S330), it can be determined that the quality of the coating film 300 is poor when there is a damaged portion on the coating film 300. On the contrary, it can be determined that the quality of the coating film 300 is good when there is no damaged portion on the coating film 300. Alternatively, even if there is a damaged portion on the coating film 300, the determination part 430 may be set to determine that the quality of the coating film 300 is good when the area of the detected damaged portion is less than the reference value.

Meanwhile, in order to increase the luminous efficiency of the coating film 300, an inspection method (S300′) of a coating film for a substrate processing apparatus according to another embodiment of the present disclosure may further include: a third coating layer formation step (S305) and a third coating layer removal step (S335) in addition to the inspection method (S300) of the coating film for a substrate processing apparatus shown in FIG. 7.

The third coating layer formation step (S305) is performed before the light irradiation step (S310), and is a step of additionally coating a third coating layer 330 on the second coating layer 320. The third coating layer 330 is a coating layer for increasing the luminous efficiency of the coating film 300, and may be a phosphor that emits light of a second wavelength when light of a first wavelength is incident and includes a matrix doped with carbon.

For example, the matrix may include one or more materials selected from yttrium oxide (Y2O3), gadolinium oxide (Gd2O3), yttrium borate (YBO3), aluminum oxide (Al2O3), zinc oxide (ZnO), cerium oxide (CeO2), and lanthanum oxide (La2O3). The matrix may maintain a state in which the second coating layer 320 to be described later and a base material 50 on which the coating film 300 according to the embodiment of the present disclosure is formed are stably bonded to each other. In addition, the matrix, as a phosphor host material, may emit light due to light irradiation when a dopant is added. For example, the matrix of the third coating layer 330 may be yttrium oxide (Y2O3).

That is, the third coating layer 330 may be of the same material as the first coating layer 310 and may be coated on the second coating layer 320.

The third coating layer removal step (S335) is performed after the coating film quality evaluation step (S330), and is a step of removing the additionally formed third coating layer 330 before applying it to a process. That is, when the inspection step of the coating film 300 is completed, the third coating layer 330 added for luminous efficiency is removed so as not to affect the subsequent plasma process. The third coating layer removal step (S335) may be performed by a polishing process or the like.

Accordingly, for easy removal, in the third coating layer formation step (S305), the third coating layer 330 may be formed to a thickness of 0.1 to 10% of the total thickness of the coating film 300.

In the above, in the present specification, evaluation of the quality of a coating film formed on a substrate processing apparatus in the manufacturing stage before being applied to a process has been described as an example. However, the present disclosure may be applied for maintenance of a substrate processing apparatus applied to a process.

The above description is merely illustrative of the technical idea of the present disclosure, and various modifications and variations may be made by those skilled in the art to which the present disclosure pertains without departing from the essential characteristics of the present disclosure. Therefore, the embodiments described in the present disclosure are not intended to limit the technical spirit of the present disclosure, but to explain, and the technical spirit of the present disclosure is not limited by these embodiments. The protection scope of the present disclosure should be construed by the following claims, and all technical ideas within the scope equivalent thereto should be construed as being included in the scope of the present disclosure.

What is claimed is:

1. An inspection method of a coating film for a substrate processing apparatus, which is for inspecting for quality of a coating film coated on a component installed in a processing space, the method comprising:
irradiating the component with light;
acquiring an image of light emitted from the coating film when the irradiating is performed; and
inspecting the coating film to inspect the quality of the coating film on the basis of the acquired image of light.

2. The inspection method of claim 1,
wherein the coating film comprises:
a first coating layer having a fluorescence property, and emitting light of a second wavelength when light of a first wavelength is incident thereon; and
a second coating layer coated on the first coating layer.

3. The inspection method of claim 2,
wherein the first coating layer is a phosphor including a matrix doped with carbon.

4. The inspection method of claim 3,
wherein the matrix includes one or more materials selected from yttrium oxide (Y2O3), gadolinium oxide (Gd2O3), yttrium borate (YBO3), aluminum oxide (Al2O3), zinc oxide (ZnO), cerium oxide (CeO2), and lanthanum oxide (La2O3).

5. The inspection method of claim 4,
wherein a carbon content of the first coating layer falls within the range of 0.01 to 10% by weight based on 100% by weight of the matrix.

6. The inspection method of claim 5,
wherein when the second coating layer is not damaged, the light emitted from the first coating layer by the light of the first wavelength passes through the second coating layer and is uniformly observed on the top of the coating film, whereas when a portion of the second coating layer is damaged, a difference between an intensity of light observed on the top of an area where the second coating layer is damaged and an intensity of light observed on the top of an area where the second coating layer is not damaged is observed.

7. The inspection method of claim 6, further comprising:
forming a third coating layer on the second coating layer before the irradiating.

8. The inspection method of claim 7,
wherein the third coating layer is formed with a thickness in the range of 0.1 to 10% of a total coating film thickness.

9. The inspection method of claim 8,
wherein the third coating layer emits light of a second wavelength when light of a first wavelength is incident thereon, and is a phosphor that includes a matrix doped with carbon.

10. The inspection method of claim 9, further comprising:
removing the third coating layer when an evaluation of the quality of the coating film is completed.

11. A substrate processing apparatus, comprising:
a base material installed in a processing space where substrates are processed; and
a coating film formed on the base material,
wherein the coating film comprises:
a first coating layer coated on the base material, having a fluorescence property, and emitting light of a second wavelength when light of a first wavelength is incident thereon; and
a second coating layer coated on the first coating layer and transmitting light emitted from the first coating layer.

12. The substrate processing apparatus of claim 11,
wherein the first coating layer is a phosphor including a matrix doped with carbon, and
wherein the matrix includes one or more materials selected from yttrium oxide (Y2O3), gadolinium oxide (Gd2O3), yttrium borate (YBO3), aluminum oxide (Al2O3), zinc oxide (ZnO), cerium oxide (CeO2), and lanthanum oxide (La2O3).

13. The substrate processing apparatus of claim 12,
wherein a carbon content of the first coating layer falls within the range of 0.01 to 10% by weight based on 100% by weight of the matrix.

14. The substrate processing apparatus of claim 13, further comprising:
an inspection unit configured to evaluate quality of the coating film,
wherein the inspection unit comprises:
a light irradiation part that irradiates the coating film with the light of the first wavelength;
a vision part that acquires an image of light emitted from the coating film by the light of the first wavelength; and
a determination part that determines a state of the coating film on the basis of the image acquired by the vision part.

15. The substrate processing apparatus of claim 14,
wherein when the light irradiation part irradiates the coating film with the light of the first wavelength, the light of the second wavelength emitted from the first coating layer passes through the second coating layer and is observed on the top of the coating film, and when a portion of the second coating layer is damaged, a difference occurs in an intensity of light observed on the top of an area where the second coating layer is damaged and an intensity of light observed on the top of an area where the second coating layer is not damaged.

16. The substrate processing apparatus of claim 15,
wherein when the portion of the second coating layer is damaged, the image acquired by the vision part includes a damaged shape of the second coating layer.

17. The substrate processing apparatus of claim 13,
wherein a thickness of the first coating layer falls within the range of 0.1 to 50% of a total coating film thickness.

18. A substrate processing apparatus, comprising:
a chamber configured to provide a processing space in which a substrate is plasma-treated;
a coating film formed on a component installed inside the chamber and exposed to plasma; and
an inspection unit configured to evaluate quality of the coating film,
wherein the coating film comprises:
a first coating layer coated on a surface of the component, having a fluorescence property, and emitting light of a second wavelength when light of a first wavelength is incident thereon; and
a second coating layer coated on the first coating layer and transmitting light emitted from the first coating layer, and
wherein the inspection unit comprises:
a light irradiation part that irradiates the coating film with light of a first wavelength;
a vision part that acquires an image of light emitted from the coating film over an entire area of the coating film by the light of the first wavelength; and
a determination part that determines a state of the coating film on the basis of the image acquired by the vision part.

19. The substrate processing apparatus of claim 18,
wherein the first coating layer is a phosphor with carbon doped in a matrix consisting of one or more materials selected from yttrium oxide (Y2O3), gadolinium oxide (Gd2O3), yttrium borate (YBO3), aluminum oxide (Al2O3), zinc oxide (ZnO), cerium oxide (CeO2), and lanthanum oxide (La2O3), and
wherein a carbon content of the first coating layer falls within the range of 0.01 to 10% by weight based on 100% by weight of the matrix.

20. The substrate processing apparatus of claim 18,
wherein when the light irradiation part irradiates the coating film with the light of the first wavelength, the light of the second wavelength emitted from the first coating layer by the light of the first wavelength passes through the second coating layer and is observed on the top of the coating film, and when a portion of the second coating layer is damaged, a difference occurs in an intensity of light observed on the top of the coating film in an area where the second coating layer is damaged and an intensity of light observed on the top of the coating film in an area where the second coating layer is not damaged.
